(19) United States
(12) Patent Application Publication
(10) Pub. No.: US 2009/0096476 A1
(43) Pub. Date: Apr. 16, 2009

(54) Method of inspecting semiconductor circuit having logic circuit as inspection circuit

(75) Inventor: Takahiro Koyama, Tokyo (JP)

Correspondence Address: FOLEY AND LARDNER LLP;SUITE 500, 3000 K STREET NW, WASHINGTON, DC, 20007, US

(73) Assignee: Elpida Memory, Inc.

(21) Appl. No.: 12/285,597

(22) Filed: Oct. 9, 2008

(30) Foreign Application Priority Data
Oct. 10, 2007 (JP) 2007-264025

(51) Int. Cl. G01R 31/02; H03K 19/00

(52) U.S. Cl. 324/763; 326/16

(57) ABSTRACT

A semiconductor circuit includes an inspection circuit for inspecting terminal open of the semiconductor circuit. The semiconductor circuit has a plurality of input terminals. The semiconductor circuit includes an input circuit portion connected to the plurality of input terminals. The inspection circuit includes a logic circuit, supplied with a plurality of input signals from the input circuit portion, for performing a predetermined logic operation to the plurality of input signals to produce a logic operation result. Whereby the semiconductor circuit enables to decide the presence or absence of the terminal open on the basis of the logic operation result.

This application is based upon and claims the benefit of priority from Japanese patent application No. 2007-264025, filed on Oct. 10, 2007, the disclosure of which is incorporated herein in its entirety by reference.

### BACKGROUND OF THE INVENTION

1. Field of the Invention

This invention relates to a semiconductor circuit and a method of inspecting the same.

2. Description of Related Art

With reduction of a semiconductor circuit, there is a problem that a test is restricted with respect to physical elements of a semiconductor testing apparatus (an LSI tester) for testing the semiconductor circuit. Although it is measures directed toward the improvement of measurement efficiency, in recent years, it becomes required to divert defective items with reliability.

Herein, in a case of testing the semiconductor circuit, to test only one semiconductor circuit very reduces efficiency. As a result, parallel (concurrently) test is carried out with a plurality of semiconductor circuits each having the same type arranged in parallel.

Various semiconductor circuits and inspection methods related to this invention are already proposed. By way of illustration, Japanese Unexamined Patent Application Publication of Tokkai No. 2005-024253 or JP-A 2005-024253 (which will be also called Patent Document 1) discloses a semiconductor device with an open inspection circuit for inspecting open (bonding failure) of power terminals and ground terminals. In the Patent Document 1, the open inspection circuit decides the bonding failure of the power terminals and the ground terminals by measuring current value passing through transistors.

The Patent Document 1 merely discloses a technical idea for inspecting open (bonding failure) in the ground terminals and does not inspect open (bonding failure) in general terminals (e.g., address input terminals, data input/output terminals, control terminals). Furthermore, the Patent Document 1 neither discloses nor teaches technique for inspecting open (bonding failure) in a plurality of input terminals at a time.

In addition, Japanese Unexamined Patent Application Publication of Tokkai No. 2000-277690 or JP-A 2000-277690 (which will later be called Patent Document 2), which corresponds to U.S. Pat. No. 6,480,979, discloses semiconductor integrated circuits and efficient parallel test methods. A semiconductor circuit disclosed in the Patent Document 2 comprises internal circuitry for implementing functions that the semiconductor circuit provides when used as a product and a selection circuit. The semiconductor circuit has a selection terminal for input of an external selection signal, control signal input terminals for input of a plurality of external control signals, and response signal output terminals for output of a plurality of response signals. When the semiconductor circuit is selected by the selection signal, the selection circuit passes the control signals received from an LSI tester at the control input terminals to the internal circuitry, and passes the response signals form the internal circuitry to the response signal output terminals, from which terminals the response signals are returned to the LSI tester. In a case of testing a plurality of semiconductor circuits by means of the LSI tester, the control input terminals of all of the semiconductor circuits are connected in common to a single set of control signal output terminals of the LSI tester and the response signal output terminals of all of the semiconductor circuits are connected in common to a single set of response signal input terminals of the LSI tester. The parallel test method comprises simultaneously sending the control signals from the LSI tester to all of the semiconductor circuits, selecting one of the semiconductor circuits in order by the selection signal, and successively sending the response signals from the selected semiconductor circuits to the LSI tester.

The Patent Document 2 merely discloses a technical idea for testing the internal circuitry of the semiconductor circuit by means of the LSI tester and neither discloses nor teaches one for testing open (bonding failure) in a plurality of input terminals of the semiconductor circuit. In addition, in order to identify (select) the semiconductor circuit in a case of a semiconductor device where a plurality of semiconductor circuits are arranged in parallel, it is necessary for individual semiconductor circuits to be provided with the selection signal input terminal for input of the external selection signal. In addition, it is necessary for the LSI tester to be provided with a plurality of selection output terminals for supplying the semiconductor circuits with the selection signals, respectively. Furthermore, it is impossible to test the semiconductor device at a time because the semiconductor circuits are selected by the selection signal in turn.

### SUMMARY

The present invention seeks to solve one or more of the above problems, or to improve upon those problems at least in part.

In one embodiment, there is provided a semiconductor circuit that includes an inspection circuit for inspecting terminal open of the semiconductor circuit. The semiconductor circuit has a plurality of input terminals. The semiconductor circuit includes an input circuit portion connected to the plurality of input terminals. The inspection circuit includes a logic circuit, supplied with a plurality of input signals from the input circuit portion, for performing a predetermined logic operation to the plurality of input signals to produce a logic operation result, whereby enabling to decide the presence or absence of the terminal open on the basis of the logic operation result.

### BRIEF DESCRIPTION OF THE DRAWINGS

The above feature and advantages of the present invention will be more apparent from the following description of certain preferred embodiments taken in conjunction with the accompanying drawing, in which:

FIG. 1 is a view for use in describing a first related tester measuring method;

FIG. 2 is a view for use in describing a second related tester measuring method;

FIG. 3 is a block diagram showing a part of an input circuit in a semiconductor circuit according a first exemplary embodiment of this invention;

FIG. 4 is a block diagram showing a modified example of the semiconductor circuit illustrated in FIG. 3;

FIG. 5 is a block diagram showing a part of an input circuit in a semiconductor circuit according a second exemplary embodiment of this invention; and

FIG. 6 is a block diagram showing a modified example of the semiconductor circuit illustrated in FIG. 5.

### DETAILED DESCRIPTION OF PREFERRED EMBODIMENTS

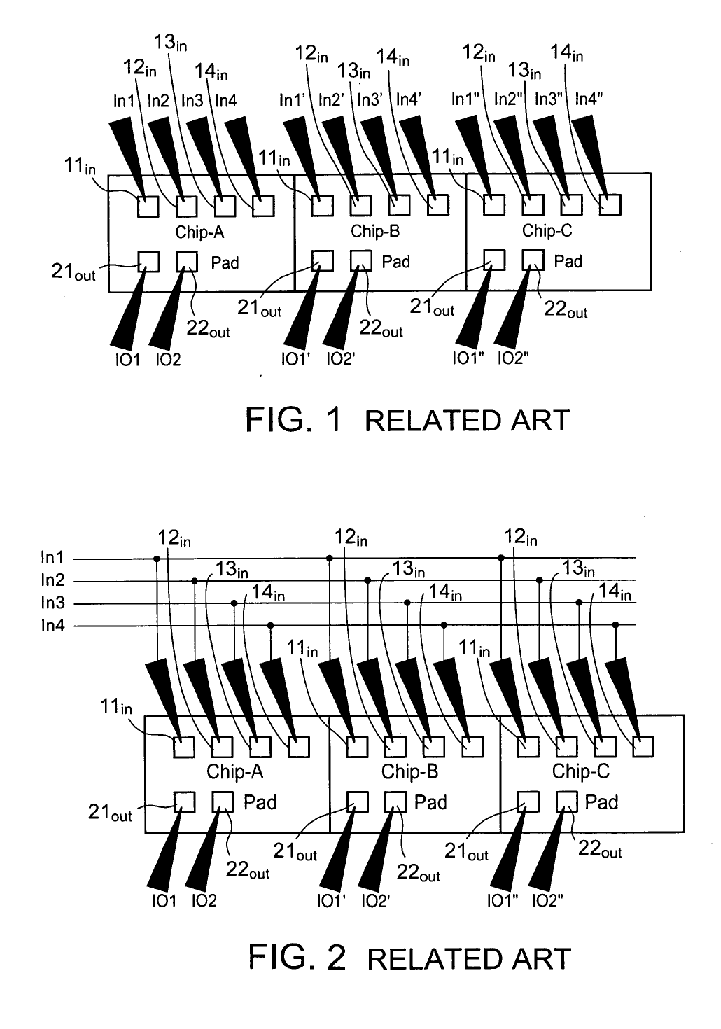

Before describing of the present invention, the related arts will be explained in detail with reference to FIGS. 1 and 2 in order to facilitate the understanding of the present invention.

FIGS. 1 and 2 are views for use in describing first and second related testing (tester measuring) methods in a case of testing, using a semiconductor testing apparatus (an LSI tester), a semiconductor device where a plurality of semiconductor circuits are arranged in parallel.

Herein, the description will be exemplified in a case where the semiconductor device comprises three semiconductor circuits (chips), namely, Chip-A, Chip-B, and Chip-C. The Chip-A is called a first semiconductor circuit (chip), the Chip-B is called a second semiconductor circuit (chip), and the Chip-C is called a third semiconductor circuit (chip). In general, the semiconductor device may comprise P semiconductor circuits, where P represents an integer which is not less than two.

In general, each semiconductor circuit has first through N-th input terminals and first through M-th input/output terminals, where each of N and M represents an integer which is not less than two. Herein, in order to simplify the description, the description will be exemplified in a case where the integer N is equal to four and the integer M is equal to two.

The first semiconductor circuit Chip-A has first through fourth input terminals 11ᵢₙ, 12ᵢₙ, 13ᵢₙ, and 14ᵢₙ and first and second input/output terminals 21ₒᵤₜ and 22ₒᵤₜ. Likewise, the second semiconductor circuit Chip-B has first through fourth input terminals 11ᵢₙ, 12ᵢₙ, 13ᵢₙ, and 14ᵢₙ and first and second input/output terminals 21ₒᵤₜ and 22ₒᵤₜ. The third semiconductor circuit Chip-C has first through fourth input terminals 11ᵢₙ, 12ᵢₙ, 13ᵢₙ, and 14ᵢₙ and first and second input/output terminals 21ₒᵤₜ and 22ₒᵤₜ. In addition, the first and the second input/output terminals 21ₒᵤₜ and 22ₒᵤₜ may be called first and second output terminals.

In the first related tester measuring method illustrated in FIG. 1, first through fourth input pins In1, In2, In3, and In4 of the LSI tester (the semiconductor testing apparatus) are assigned to the first through the fourth input terminals 11ᵢₙ to 14ᵢₙ of the first semiconductor chip Chip-Awhile first and second input/output pins IO1 and IO2 of the LSI tester (the semiconductor testing apparatus) are assigned to the first and the second input/output terminals 21ₒᵤₜ and 22ₒᵤₜ of the first semiconductor chip Chip-A. Similarly, fifth through eighth input pins In1′, In2′, In3′, and In4′ of the LSI tester (the semiconductor testing apparatus) are assigned to the first through the fourth input terminals 11ᵢₙ to 14ᵢₙ of the second semiconductor chip Chip-B while third and fourth input/output pins IO1′ and IO2′ of the LSI tester (the semiconductor testing apparatus) are assigned to the first and the second input/output terminals 21ₒᵤₜ and 22ₒᵤₜ of the second semiconductor chip Chip-B. Ninth through twelfth input pins In1″, In2″, In3″, and In4″ of the LSI tester (the semiconductor testing apparatus) are assigned to the first through the fourth input terminals 11ᵢₙ to 14ᵢₙ of the third semiconductor chip Chip-C while fifth and sixth input/output pins IO1″ and IO2″ of the LSI tester (the semiconductor testing apparatus) are assigned to the first and the second input/output terminals 21ₒᵤₜ and 22ₒᵤₜ of the third semiconductor chip Chip-C.

Therefore, the number of the input pins of the LSI tester (the semiconductor testing apparatus) requires the number obtained by multiplying “the number of input terminals” of the semiconductor circuit by “simultaneous measuring number”. In addition, the number of the input/output pins of the LSI tester (the semiconductor testing apparatus) requires the number obtained by multiplying “used number” for carrying out test determination of individual semiconductor circuit by “simultaneous measuring number”.

The second related tester measuring method illustrated in FIG. 2 is made commonality of the same input signals with respect to the first related tester measuring method illustrated in FIG. 1. More specifically, in the second related tester measuring method, the first through the fourth input pins In1, In2, In3, and In4 of the LSI tester (the semiconductor testing apparatus) are commonly assigned to the first through the fourth input terminals 11ᵢₙ to 14ᵢₙ of the first semiconductor chip Chip-A, to the first through the fourth input terminals 11ᵢₙ to 14ᵢₙ of the second semiconductor chip Chip-B, and to the first through the fourth input terminals 11ᵢₙ to 14ᵢₙ of the third semiconductor chip Chip-C.

In the manner which is described above, in the second related tester measuring method, by commonality of the same input signals, it is possible to decrease the number of wiring of the semiconductor testing apparatus (the LSI tester) to increase the simultaneous measuring number. However, the input/output pins are normally not made commonality.

There is a problem in the second related tester measuring method illustrated in FIG. 2 as follows. In the second related tester measuring method, it is impossible to detect an open pin failure although it is possible to increase of the simultaneous measuring number by making commonality of the same signal lines.

Conventionally, detection of the open pin failure is carried out as follows. Specifically, a failure product is detected by supplying a measurement pin with a negative voltage and by determining continuity or nonconducting by whether or not current flows.

However, in the second related tester measuring method illustrated in FIG. 2, there is a problem that it is impossible to identify a defective semiconductor circuit because commonality of the signal lines although it is possible to detect any abnormality by measuring a current value.

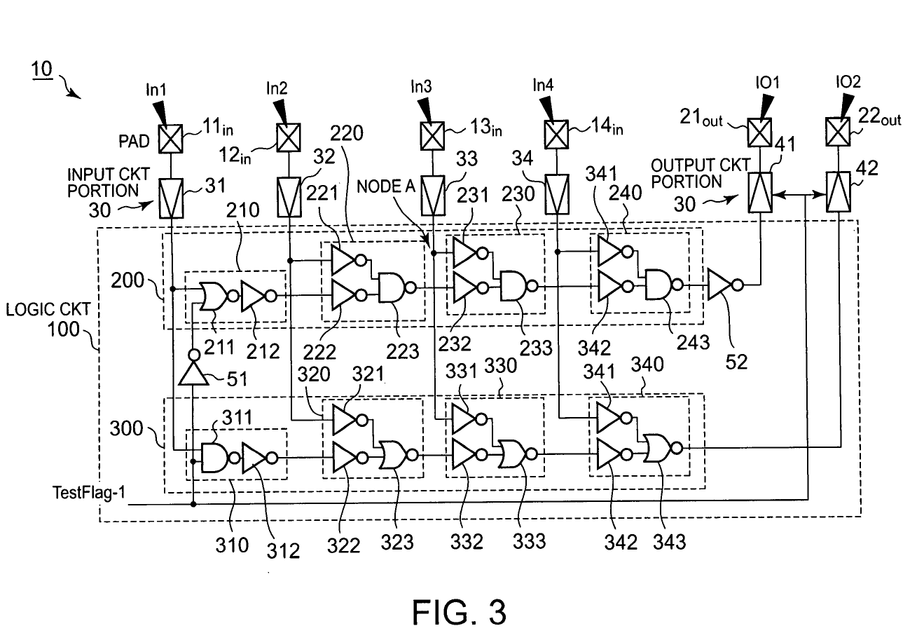

Referring to FIG. 3, the description will proceed to a semiconductor circuit 10 according to a first embodiment of the present invention. FIG. 3 illustrates a part of an input circuit of the semiconductor circuit 10 and shows an example which uses a logic circuit 100 as an inspection circuit of the semiconductor circuit 10.

In general, in the manner which is described above, the semiconductor circuit has first through N-th input terminals and first through M-th output terminals (input/output terminals), where each of N and M represents an integer which is not less than two. Herein, in order to simplify the description, the description will be exemplified in a case where the integer N is equal to four and the integer M is equal to two.

The illustrated semiconductor circuit 10 has first through fourth input terminals 11ᵢₙ, 12ᵢₙ, 13ᵢₙ and 14ᵢₙ and first and second output terminals 21ₒᵤₜ and 22ₒᵤₜ. The first through the fourth input terminals 11ᵢₙ to 14ᵢₙ are connected to first through fourth input terminals of other semiconductor circuits in the manner as shown in FIG. 2. The first through the fourth input terminals are supplied with input signals from first through fourth input pins In1, In2, In3, and In4 of a semiconductor testing apparatus (not shown) in common. First and second input/output pins IO1 and IO2 of the semiconductor testing apparatus are used (assigned) to the first and the second output terminals 21ₒᵤₜ and 22ₒᵤₜ so as to enable to identify the semiconductor circuit, individually, in the manner as shown in FIG. 2.

The semiconductor circuit 10 comprises an input circuit portion 30 connected to the first through the fourth input terminals 11ᵢₙ to 14ᵢₙ and an output circuit portion 40 connected to the first and the second output terminals 21ₒᵤₜ and 22ₒᵤₜ. As shown in FIG. 3, the logic circuit 100 is inserted or sandwiched between the input circuit portion 30 and the output circuit portion 40. In addition, although illustration is not made, the semiconductor circuit 10 comprises an internal circuit therewithin that is connected to the input circuit portion 30 and the output circuit portion 40. The internal circuit is a circuit for realizing a function as a product.

In the example being illustrated, the input circuit portion 30 comprises first through fourth input buffers 31, 32, 33, and 34 which are connected to the first through the fourth input terminals 11ᵢₙ to 14ᵢₙ respectively. The output circuit portion 40 comprises first and second output buffers 41 and 42 which are connected to the first and the second output terminals 21ₒᵤₜ and 22ₒᵤₜ, respectively.

The semiconductor circuit 10 is supplied with a signal TestFlag-1. The signal TestFlag-1 is an enable signal on carrying out a test of the semiconductor circuit 10 in question. On testing, the enable signal TestFlag-1 is a signal having a logic “H” level so that the logic circuit 100 and the output circuit portion 40 are put into an enable state.

The logic circuit 100 is a circuit which is supplied with outputs of the input circuit portion 30 as inputs thereof and which carries out a predetermined logic operation to a plurality of input signals to produce a logic operation result. The inspection circuit (the logic circuit) 100 is enable to decide a terminal open of the semiconductor circuit 10 in accordance with the logic operation result.

The illustrated logic circuit 100 comprises two different logic circuit portions. In the example being illustrated, the logic circuit 100 comprises, as the two different logic circuit portions, an OR circuit portion 200 and an AND circuit portion 300. However, the logic circuit is not restricted to that illustrated in FIG. 3, the logic circuit may comprise one logic circuit portion or three or more different logic circuit portions. In addition, the logic circuit portions are not restricted to a combination of the OR circuit portion 200 and the AND circuit portion 300, a combination of various logic circuit portions may be used.

It will be assumed that all of the first through the fourth input terminals 11ᵢₙ to 14ᵢₙ are supplied with the input signals each having the logic “L” level. In this event, the OR circuit portion 200 is configured so as to produce a signal of the logic “L” level if there is no abnormality in or nothing wrong with the first through the fourth input terminals 11ᵢₙ to 14ᵢₙ.

On the other hand, it will be presumed that all of the first through the fourth input terminals 11ᵢₙ to 14ᵢₙ are supplied with the input signals each having the logic “H” level. In this event, the AND circuit portion 300 is configured so as to produce a signal of the logic “H” level if there is no abnormality in or nothing wrong with the first through the fourth input terminals 11ᵢₙ to 14ᵢₙ.

In the example being illustrated, the OR circuit portion 200 comprises first through fourth OR circuits 210, 220, 230, and 240. Each of the first through the fourth OR circuits 210 to 240 is configured to a 2-input OR circuit. The first through the fourth OR circuits 210 to 240 are cascade connected to each other. That is, the OR circuit portion 200 comprises the first through the fourth 2-input OR circuits 210 to 240 which are cascade connected to the first through the fourth input terminals 11ᵢₙ to 14ᵢₙ through the input circuit portion 30.

More specifically, the first OR circuit 210 has one input port connected to the input terminal 11ᵢₙ through the first input buffer 31 and anther input port supplied with the enable signal TestFlag-1 through an inverter 51. The second OR circuit 220 has one input port connected to the first input terminal 12in through the second input buffer 32 and another input port supplied with an output signal of the first OR circuit 210. Likewise, the third OR circuit 230 has one input port connected to the third input terminal 13in through the third input buffer 33 and another input port supplied with an output signal of the second OR circuit 220. The fourth OR circuit 240 has one input port connected to the fourth input terminal 14ᵢₙ through the fourth input buffer 34 and another input port supplied with an output signal of the third OR circuit 230. The fourth OR circuit 240 produces an output signal which is supplied to the first output terminal 21ₒᵤₜ through an inverter 52 and the first output buffer 41.

In the example being illustrated, the first OR circuit 210 comprises a NOR gate 211 and an inverter gate 212. The NOR gate 211 carries out NOR operation between the input signal supplied from the input terminal 11ᵢₙ through the first input buffer 31 and a signal obtained by inverting the enable signal TestFlag-1 by the inverter 51 to produce a NOR operation result signal. The inverter gate 212 inverts the NOR operation result signal to produce an inverted signal as the output signal of the first OR circuit 210.

The second OR circuit 220 comprises two inverter gates 221 and 222 and a NAND gate 223. The inverter gate 221 inverts the input signal supplied from the second input terminal 12ᵢₙ through the second input buffer 32 to produce a first inverted signal. The inverter gate 222 inverts the output signal of the first OR circuit 210 to produce a second inverted signal. The NAND gate 223 carries out NAND operation between the output signal of the inverter gate 221 (the first inverted signal) and the output signal of the inverter gate 222 (the second inverted signal) to produce a NAND operation result signal as the output signal of the second OR circuit 220.

Similarly, the third OR circuit 230 comprises two inverter gates 231 and 232 and a NAND gate 233. The inverter gate 231 inverts the input signal supplied from the third input terminal 13ᵢₙ through the third input buffer 33 to produce a first inverted signal. The inverter gate 232 inverts the output signal of the second OR circuit 220 to produce a second inverted signal. The NAND gate 233 carries out NAND operation between the output signal of the inverter gate 231 (the first inverted signal) and the output signal of the inverter gate 232 (the second inverted signal) to produce a NAND operation result signal as the output signal of the third OR circuit 230.

The fourth OR circuit 240 comprises two inverter gates 241 and 242 and a NAND gate 243. The inverter gate 241 inverts the input signal supplied from the fourth input terminal 14ᵢₙ through the fourth input buffer 34 to produce a first inverted signal. The inverter gate 242 inverts the output signal of the third OR circuit 230 to produce a second inverted signal. The NAND gate 243 carries out NAND operation between the output signal of the inverter gate 241 (the first inverted signal) and the output signal of the inverter gate 242 (the second inverted signal) to produce a NAND operation result signal as the output signal of the fourth OR circuit 240.

The output signal of the fourth OR circuit 240 is supplied to the inverter 52 as the output signal of the OR circuit portion 200. The inverter 52 inverts the output signal of the OR circuit portion 200 to produce an inverted signal to the first output terminal 21ₒᵤₜ through the first output buffer 41.

It will be assumed that the first through the fourth input terminals 11ᵢₙ to 14ᵢₙ are supplied from the first through the fourth input pins In1 to In4 with the input signals with all the logic “L” level. In this event, inasmuch as the OR circuit portion 200 produces a signal of the logic “L” level, the signal of the logic “L” level is inverted by the inverter 52 and thereby the first output terminal 21ₒᵤₜ produces a signal having the logic “H” level through the first output buffer 41.

On the other hand, it will be presumed that the first through the fourth input terminals 11ᵢₙ to 14ᵢₙ are supplied from the first through the fourth input pins In1 to In4 with the input signals excepting all the logic “L” level. In this event, inasmuch as the OR circuit portion 200 produces a signal of the logic “H” level, the signal of the logic “H” level is inverted by the inverter 52 and thereby the first output terminal 21ₒᵤₜ produces a signal having the logic “L” level through the first output buffer 41.

The AND circuit portion 300 comprises first through fourth AND circuits 310, 320, 330, and 340. Each of the first through the fourth AND circuits 310 to 340 is configured by a 2-input AND circuit. The first through the fourth AND circuits 310 to 340 are cascade connected to each other. That is, the AND circuit portion 300 comprises the first through the fourth 2-input AND circuits 310 to 340 which are cascade connected to the first through the fourth input terminals 11ᵢₙ to 14ᵢₙ through the input circuit portion 30.

More specifically, the first AND circuit 310 has one input port connected to the first input terminal 11ᵢₙ through the first input buffer 31 and another input port supplied with the enable signal TestFlag-1. The second AND circuit 320 has one input port connected to the second input terminal 12ᵢₙ through the second input buffer 32 and another input port supplied with an output signal of the first AND circuit 310. Likewise, the third AND circuit 330 has one input port connected to the third input terminal 13ᵢₙ through the third input buffer 33 and another input port supplied with an output signal of the second AND circuit 320. The fourth AND circuit 340 has one input port connected to the fourth input terminal 14ᵢₙ through the fourth input buffer 34 and another input port supplied with an output signal of the third AND circuit 330. The fourth AND circuit 340 produces an output signal which is supplied to the second output terminal 22ₒᵤₜ through the second output buffer 42.

In the example being illustrated, the first AND circuit 310 comprises a NAND gate 311 and an inverter gate 312. The NAND gate 311 carries out NAND operation between the input signal supplied from the first input terminal 11ᵢₙ through the first input buffer 31 and the enable signal TestFlag-1 to produce a NAND operation result signal. The inverter gate 312 inverts the NAND operation result signal to produce an inverted signal as the output signal of the first AND circuit 310.

The second AND circuit 320 comprises two inverter gates 321 and 322 and a NOR gate 323. The inverter gate 321 inverts the input signal supplied from the second input terminal 12ᵢₙ through the second input buffer 32 to produce a first inverted signal. The inverter gate 322 inverts the output signal of the firstAND circuit 310 to produce a second inverted signal. The NOR gate 323 carries out NOR operation between the output signal of the inverter gate 321 (the first inverted signal) and the output signal of the inverter gate 322 (the second inverted signal) to produce a NOR operation result signal as the output signal of the second AND circuit 320.

Similarly, the third AND circuit 330 comprises two inverter gates 331 and 332 and a NOR gate 333. The inverter gate 331 inverts the input signal supplied from the third input terminal 13ᵢₙ through the third input buffer 33 to produce a first inverted signal. The inverter gate 332 inverts the output signal of the second AND circuit 320 to produce a second inverted signal. The NOR gate 333 carries out NOR operation between the output signal of the inverter gate 331 (the first inverted signal) and the output signal of the inverter gate 332 (the second inverted signal) to produce a NOR operation result signal as the output signal of the third AND circuit 330.

The fourth AND circuit 340 comprises two inverter gates 341 and 342 and a NOR gate 343. The inverter gate 341 inverts the input signal supplied from the fourth input terminal 14ᵢₙ through the fourth input buffer 34 to produce a first inverted signal. The inverter gate 342 inverts the output signal of the third AND circuit 330 to produce a second inverted signal. The NOR gate 343 carries out NOR operation between the output signal of the inverter gate 341 (the first inverted signal) and the output signal of the inverter gate 342 (the second inverted signal) to produce a NOR operation result signal as the output signal of the fourth AND circuit 340.

The output signal of the fourth AND circuit 340 is supplied to the second output terminal 22ₒᵤₜ through the second output buffer 42 as the output signal of the AND circuit portion 300.

It will be assumed that the first through the fourth input terminals 11ᵢₙ to 14ᵢₙ are supplied from the first through the fourth input pins In1 to In4 with the input signals with all the logic “H” level. In this event, inasmuch as the AND circuit portion 300 produces the output signal having the logic “H” level, the signal of the logic “H” level is produced by the second output terminal 22ₒᵤₜ though the second output buffer 42.

On the other hand, it will be presumed that the first through the fourth input terminals 11ᵢₙ to 14ᵢₙ are supplied from the first through the fourth input pins In1 to In4 with the input signals excepting all the logic “H” level. In this event, inasmuch as the AND circuit portion 300 produces a signal having the logic “L” level, the signal having the logic “L” level is produced by the second output terminal 22ₒᵤₜ through the second output buffer 42.

That is to say, it will be assumed that the first through the fourth input terminals 11ᵢₙ to 14ᵢₙ are supplied from the first through the fourth input pins In1 to In4 with the input signals with all the logic “H” level or all the logic “L” level. In addition, it will be assumed that the first and the second output terminals 21ₒᵤₜ and 22ₒᵤₜ produce the output signals which have opposite phases. Under the circumstances, it is possible to decide that the semiconductor circuit 10 is normal, namely, there is no open failure.

Conversely, it will be assumed that the first and the second output terminals 21ₒᵤₜ and 22ₒᵤₜ produce the output signals which are in phase with each other. In this event, it is considered that the input terminals for the logic circuit 100 have any defect. With these results, it is possible to carry out decision of a terminal open test.

In the terminal open test, it will be assumed, for example, that a break occurs in a wiring between the third input terminal 13ᵢₙ and a node A as shown in FIG. 3. In this event, it is considered that the node A has a level which is either the logic “H” level or the logic “L” level.

It will be presumed that the node A has the logic “H” level. Under the circumstances, it will be presumed that the first through the fourth input terminals 11ᵢₙ to 14ᵢₙ are supplied from the first though the fourth input pins In1 to In4 with the input signals with all the logic “L” level. In this event, inasmuch as the output signal of the third OR circuit 230 has the logic “H” level, the first output terminal 21ₒᵤₜ produces the first output signal having the logic “L” level. At this time, the second output terminal 22ₒᵤₜ produces the second output signal having the logic “L” level. That is, inasmuch as the first and the second output signals obtained by the first and the second output terminals 21ₒᵤₜ and 22ₒᵤₜ are in phase to each other, it is possible to detect (decide) a defect or a fault in the semiconductor circuit 10.

On the other hand, it will be presumed that the node A has the logic “L” level. Under the circumstances, it will be presumed that the first through the fourth input terminals 11ᵢₙ to 14ᵢₙ are supplied from the first through the fourth input pins In1 to In4 with the input signals with all the logic “H” level. In this even, inasmuch as the output signal of the third AND circuit 330 has the logic “L” level, the second output terminal 22ₒᵤₜ produces the second output signal having the logic “L” level. At this time, the first output terminal 21ₒᵤₜ produces the first output signal having the logic “L” level. That is, inasmuch as the first and the second output signals obtained by the first and the second output terminals 21ₒᵤₜ and 22ₒᵤₜ are in phase (in consonance) with each other, it is possible to detect (decide) a defect or a fault of the semiconductor circuit 10.

In sum, when the terminal open defect occurs, it is considered that the node A becomes either the logic “H” level or the logic “L” level. Therefore, by supplying twice from the first through the fourth input pins In1 to In4 to the first through the fourth input terminals 11ᵢₙ to 14ᵢₙ with the input signals with all the logic “L” level and the input signals with all the logic “H” level, it is possible to certainly detect the terminal open defect of the semiconductor circuit 10.

More specifically, test of the terminal open in the semiconductor circuit 10 comprising the logic circuit 100 illustrated in FIG. 3 is carried out as follows. First, all of the first through the fourth input terminals 11ᵢₙ to 14ᵢₙ are supplied with one of the logic “H” level and the logic “L” level. Subsequently, all of the first through the fourth input terminals 11ᵢₙ to 14ᵢₙ are supplied with another of the logic “H” level and the logic “L” level. Thus, it is possible to decide the presence or absence of the terminal open in the semiconductor circuit 10 in accordance with a level of the output signal of the logic circuit 100.

As a result of this, it is possible to detect the presence or absence of open pin defect in the semiconductor circuits, individually, even if commonality of the input signals is carried out as shown in FIG. 2.

More specifically, test of the terminal open in the semiconductor device where a plurality of semiconductor circuits each illustrated in FIG. 3 that are arranged in parallel is carried out as follows. First, the first through the fourth input terminals 11ᵢₙ to 14ᵢₙ of all of the semiconductor circuits 10 are connected in common to the first through the fourth input pins In1 to In4 of the semiconductor testing apparatus (the LSI tester), respectively. Then, all of the first through the fourth input terminals 11ᵢₙ to 14ᵢₙ are supplied with one of the logic “H” level and the logic “L” level. Subsequently, all of the first through the fourth input terminals 11ᵢₙ to 14ᵢₙ are supplied with another of the logic “H” level and the logic “L” level. Thus, it is possible to decide the presence or absence of the terminal open in the semiconductor device where the plurality of the semiconductor circuits 10 are arranged in parallel in accordance with a level of the output signals of the logic circuit 100. That is, it is possible to identify the semiconductor circuit 10 having the open pin defect and it is possible to improve measurement efficiency.

It will be assumed that the number of the input terminals of the semiconductor circuit 10 is increased. In this event, it is possible to support by increasing the number of the OR circuits and the AND circuits making up the logic circuit 100 in the similar manner and a result obtained on testing is similar thereto.

On testing the semiconductor device where a plurality of semiconductor circuits each illustrated in FIG. 3 are arranged in parallel, although the same type of input signals are made commonality in order to increase the simultaneous measurement number, it is possible for the semiconductor circuit 10 having the logic circuit 100 illustrated in FIG. 3 to identify the semiconductor circuit having the open pin fault. As a result, it is possible to improve the measurement efficiency.

On measurement, input signals such as address signals, other control signals, or the like may be made commonality. For example, it will be assumed that test is simultaneously made to ten semiconductor circuits each having twenty input terminals and two input/output terminals. In this event, in the first related tester measuring method as shown in FIG. 1, it is necessary for the semiconductor testing apparatus (the LSI tester) to have two hundreds input pins and twenty input/output pins. In comparison with this, by implementing the semiconductor circuit 10 comprising the logic circuit 100 illustrated in FIG. 3, it is possible to maintain the semiconductor testing apparatus (the LSI tester) having twenty input pins and twenty input/output pins. As a result, in the semiconductor testing apparatus (the LSI tester) for testing the semiconductor device where a plurality of semiconductor circuits 10 are arranged in parallel, it is possible to decrease the number of signal lines, to increase the simultaneous measurement number, and to detect the open pin defect in the manner as conventionally.

In the semiconductor circuit 10 illustrated in FIG. 3, the presence or absence of the open pin defect is decided so that it is normal (there is no open pin defect) if the output signals obtained by the first and the second output terminals 21ₒᵤₜ and 22ₒᵤₜ are inverted (opposite phase) with each other and so that it is defective (there is any open pin defect) if the output signals obtained by the first and the second output terminals 21ₒᵤₜ and 22ₒᵤₜ are coincidence (in phase) with each other. For this purpose, the logic circuit (the inspection circuit) 100 comprises the inverter 52 at the output side of the OR circuit portion 200. However, the inverter 52 may be omitted from the logic circuit 100.

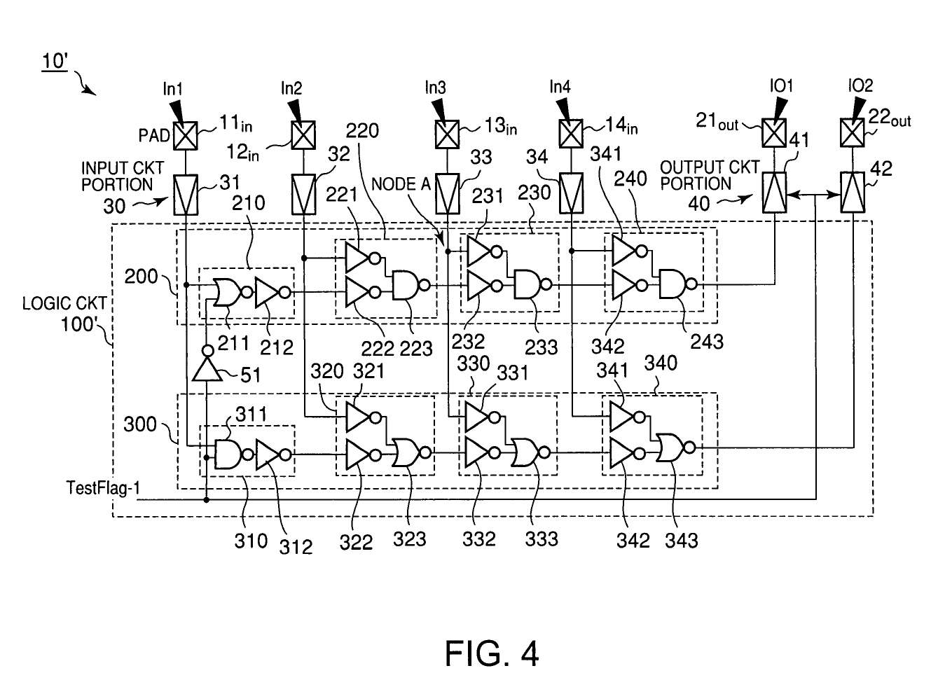

FIG. 4 shows a semiconductor circuit 10′ where the inverter 52 is omitted from the semiconductor circuit 10 illustrated in FIG. 3. That is, the semiconductor circuit 10′ has similar structure to the semiconductor circuit 10 illustrated in FIG. 3 except that the logic circuit 100 is modified to a logic circuit 100′. Components having structure similar to those illustrated in FIG. 3 are depicted at similar reference symbols and the description thereto will be omitted in order to simplify the description.

The logic circuit 100′ serving as the inspection circuit has similar structure to the logic circuit 100 illustrated in FIG. 3 except that the inverter 52 is omitted. Specifically, the logic circuit 100′ comprises the OR circuit portion 200, the AND circuit portion 300, and the inverter 51. The output signal of the OR circuit portion 200 is supplied to the first output terminal 21ₒᵤₜ through the first output buffer 41.

In the semiconductor circuit 10′ illustrated in FIG. 4, the presence or absence of the open pin defect is decided so that it is normal (there is no open pin defect) if the first and the second output signals obtained by the first and the second output terminals 21ₒᵤₜ and 22ₒᵤₜ are coincident (in phase) with each other and so that it is abnormal (there is any open pin defect) if the first and the second output signals obtained by the first and the second output terminals 21ₒᵤₜ and 22ₒᵤₜ are inverted (opposite phase) with each other.

More specifically, the inspection of the terminal open in the semiconductor circuit 10′ comprising the logic circuit 100′ illustrated in FIG. 4 is carried out as follows. First, all of the first through the fourth input terminals 11ᵢₙ to 14ᵢₙ are supplied with one of the logic “H” level and the logic “L” level. Subsequently, all of the first through the fourth input terminals 11ᵢₙ to 14ᵢₙ are supplied with another of the logic “H” level and the logic “L” level. Thus, it is possible to decide the presence or absence of the terminal open in the semiconductor circuit 10′ in accordance with a level of the output signal of the logic circuit 100′.

In addition, test of the terminal open in the semiconductor device where a plurality of semiconductor circuits each illustrated in FIG. 4 that are arranged in parallel is carried out in the manner which is described above.

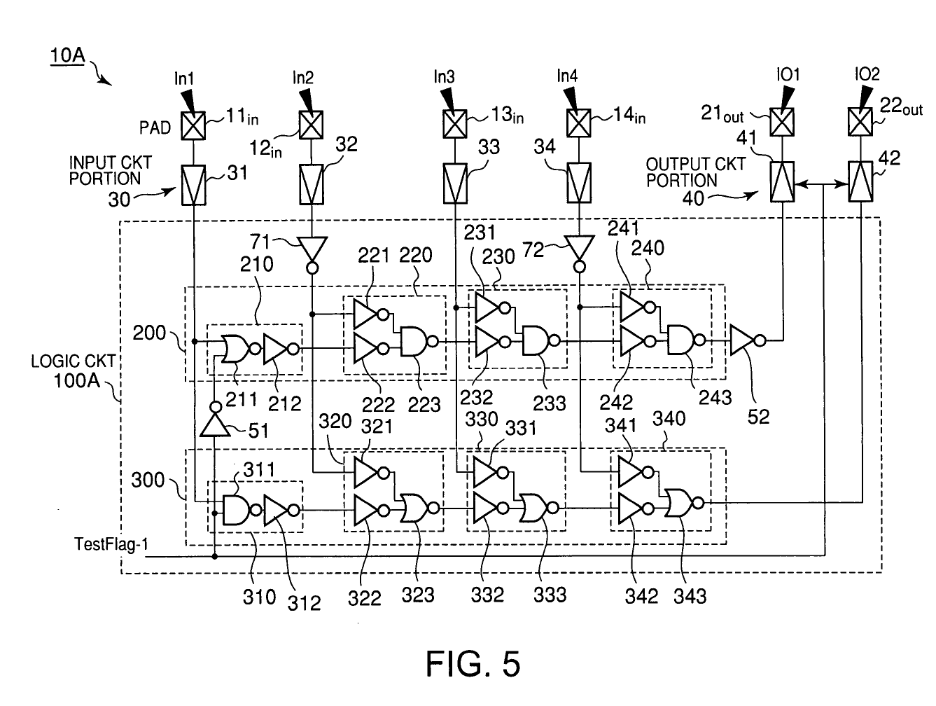

Referring to FIG. 5, the description will proceed to a semiconductor circuit 10A according to a second embodiment of the present invention. FIG. 5 illustrates a part of an input circuit of the semiconductor circuit 10A and shows an example which uses a logic circuit 100A as an inspection circuit of the semiconductor circuit 10A.

The illustrated logic circuit 100A is similar in structure and operation to the logic circuit 100 illustrated in FIG. 3 except that first and second inverters 71 and 72 are added thereto. Components having structure similar to those illustrated in FIG. 3 are depicted at similar reference symbols and only different points will be described in order to simplify the description.

The first inverter 71 is inserted between the second input buffer 32 and the one input port of the second OR circuit 220 in the OR circuit portion 200. In other words, supplied to the second input terminal 12ᵢₙ, the input signal is supplied to the first inverter 71 through the second input buffer 32 and is inverted by the first inverter 71 into a first inverted signal which is supplied to the one input port of the second OR circuit 220 in the OR circuit portion 200 and to the one input port of the second AND circuit 320 in the AND circuit portion 300.

Likewise, the second inverter 72 is inserted between the fourth input buffer 34 and the one input port of the fourth OR circuit 240 in the OR circuit portion 200. In other words, supplied to the fourth input terminal 14ᵢₙ, the input signal is supplied to the second inverter 72 through the fourth input buffer 34 and is inverted by the second inverter 72 into a second inverted signal which is supplied to the one input port of the fourth OR circuit 240 in the OR circuit portion 200 and to the one input port of the fourth AND circuit 340 in the AND circuit portion 300.

That is, the inspection circuit (the logic circuit) 100A comprises the first and the second inverters 71 and 72 which alternately invert the input signals from the first through the fourth input terminals 11ᵢₙ to 14ᵢₙ through the input circuit portion 30.

The semiconductor circuit 10A comprising the illustrated logic circuit 100A carries out the test by supplying from the first through the fourth input pins In1 to In4 to the first through the fourth input terminals 11ᵢₙ to 14ᵢₙ with a bit parallel input signal of “HLHL” or “LHLH”. Hereby, a result similar to that of the first embodiment illustrated in FIG. 3 is obtained.

Herein, the signal of “HLHL” is referred to as a bit parallel first input signal while the signal of “LHLH” is referred to as a bit parallel second input signal. However, the signal of “LHLH” may be called the bit parallel first input signal while the signal of “HLHL” may be called the bit parallel second input signal.

In other words, the test of the terminal open in the semiconductor circuit 10A is carried out as follows. First, the first through the fourth input terminals 11ᵢₙ to 14ᵢₙ are supplied with the bit parallel first input signal “HLHL” where logic levels are inverted in turn. Thereafter, the first through the fourth input terminals 11ᵢₙ to 14ᵢₙ are supplied with the bit parallel second input signal “LHLH” which is obtained by inverting the bit parallel first input signal. Hence, it is possible to decide the presence or absence of the terminal open in the semiconductor circuit 10A in accordance with a level of the output signal of the logic circuit 100A.

In the semiconductor circuit 10 comprising the logic circuit 100 illustrated in FIG. 3, if adjacent input terminals are shunted, there may be a case where such abnormality is not detected because in-phase signals are transferred.

As compared with this, in the semiconductor circuit 10A comprising the logic circuit 100A illustrated in FIG. 5, adjacent input signals are inverted by supplying the first through the fourth input terminals 11ᵢₙ to 14ᵢₙ with the input signal of “HLHL” or “LHLH”. As a result of this, it is possible to work around the above-mentioned case. A result obtained by the first and the second output terminals 21ₒᵤₜ and 22ₒᵤₜ is similar to that of the first embodiment illustrated in FIG. 3.

In addition, test of the terminal open in the semiconductor device where a plurality of semiconductor circuits 10A each comprising the logic circuit 100A illustrated in FIG. 5 that are arranged in parallel is carried out as follows. First, the first through the fourth input terminals 11ᵢₙ to 14ᵢₙ of all of the semiconductor circuits 10A are connected to the first through the fourth input pins In1 to In4 of the semiconductor testing apparatus (the LSI tester) in common, respectively. Then, the first through the fourth input terminals 11ᵢₙ to 14ᵢₙ are supplied with the bit parallel first input signal “HLHL” where logic levels are inverted in turn. Thereafter, the first through the fourth input terminals 11ᵢₙ to 14ᵢₙ are supplied with the bit parallel second input signal ‘LHLH” which is obtained by inverting the bit parallel first input signal. Thus, it is possible to decide the presence or absence of the terminal open in the semiconductor device where the plurality of semiconductor circuits 10A are arranged in parallel in accordance with a level of the output signal of the logic circuit 100A. That is, it is possible to identify the semiconductor circuit 10A having the open pin defect and it is possible to improve measurement efficiency.

In the manner which is similar to that in a case of the semiconductor circuit 10 illustrated in FIG. 3, in the semiconductor circuit 10A illustrated in FIG. 5, the presence or absence of the open bin defect is decided so that it is normal (there is no open pin defect) if the first and the second output signals obtained by the first and the second output terminals 21ₒᵤₜ and 22ₒᵤₜ are inverted (opposite phase) with each other and so that it is abnormal (there is any open pin defect) if the first and the second output signals obtained by the first and the second output terminals 21ₒᵤₜ and 23ₒᵤₜ are coincident (in phase) with each other. Therefore, the logic circuit (the inspection circuit) 100A comprises the inverter 52 at an output side of the OR circuit portion 200. However, the inverter 52 may be omitted from the logic circuit 100A.

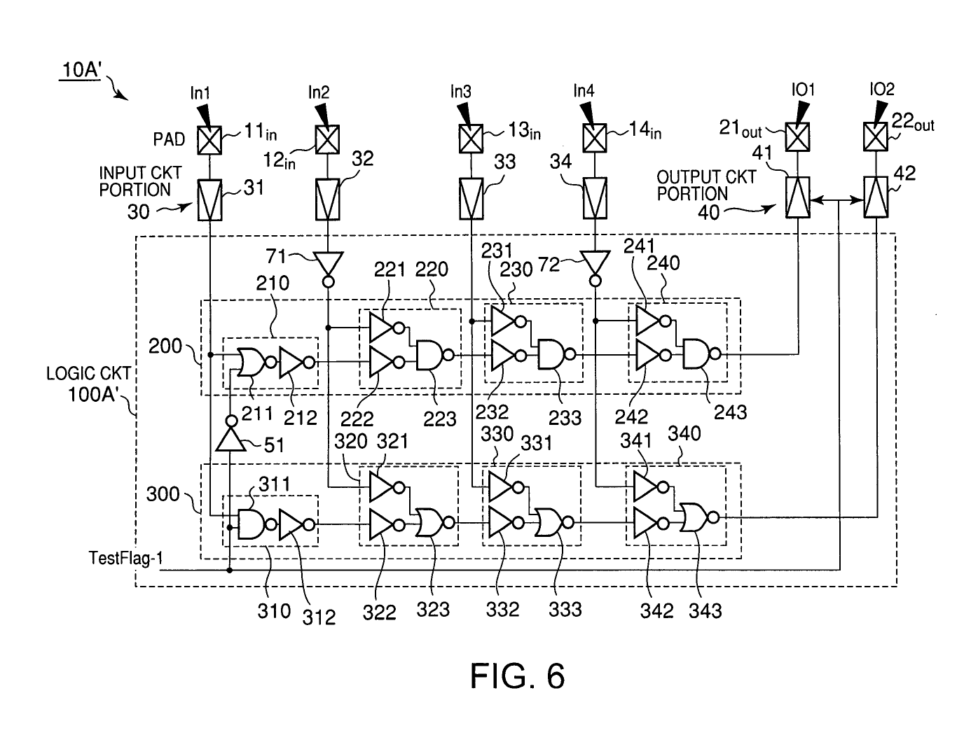

FIG. 6 shows a semiconductor circuit 10A′ where the inverter 52 is omitted from the semiconductor circuit 10A illustrated in FIG. 5. That is, the semiconductor circuit 10A′ has similar structure to the semiconductor circuit 10A illustrated in FIG. 5 except that the logic circuit 100A is modified to a logic circuit 100A′. Components having structure similar to those illustrated in FIG. 5 are depicted at similar reference symbols and the description thereto will be omitted in order to simplify the description.

The logic circuit 100A′ serving as the inspection circuit has similar structure to the logic circuit 100A illustrated in FIG. 5 except that the inverter 52 is omitted. Specifically, the logic circuit 100A′ comprises the OR circuit portion 200, the AND circuit portion 300, the inverter 51, and the first and the second inverters 71 and 72. The output signal of the OR circuit portion 200 is supplied to the first output terminal 21ₒᵤₜ through the first output buffer 41.

In the semiconductor circuit 10A′ illustrated in FIG. 6, the presence or absence of the open pin defect is decided so that it is normal (there is no open pin defect) if the first and the second output signals obtained by the first and the second output terminals 21ₒᵤₜ and 22ₒᵤₜ are coincident (in phase) with each other and so that it is abnormal (there is any open pin defect) if the first and the second output signals obtained by the first and the second output terminals 21ₒᵤₜ and 22ₒᵤₜ are inverted (opposite phase) with each other.

More specifically, the inspection of the terminal open in the semiconductor circuit 10A′ is carried out as follows. First, the first through the fourth input terminals 11ᵢₙ to 14ᵢₙ are supplied with the bit parallel first input signal “HLHL” where logic levels are inverted in turn. Subsequently, the first through the fourth input terminals 11ᵢₙ to 14ᵢₙ are supplied with the bit parallel second input signal “LHLH” which is obtained by inverting the bit parallel first input signal. Thus, it is possible to decide the presence or absence of the terminal open in the semiconductor circuit 10A′ in accordance with a level of the output signal of the logic circuit 100A′.

In addition, test of the terminal open in the semiconductor device where a plurality of semiconductor circuits 10A′ each comprising the logic circuit 100A′ illustrated in FIG. 6 that are arranged in parallel is carried out in the manner which is described above.

It is apparent that the present invention is not limited to the above embodiments, but may be modified and changed without departing from the scope and spirit of the invention. For example, although a combination of the OR circuit portion and the AND circuit portion is used as the logic circuit in the above-mentioned embodiments, any logic circuit may be used as long as it is possible to detect the open pin defect.

1. A semiconductor circuit comprising an inspection circuit for inspecting terminal open of said semiconductor circuit, said semiconductor circuit having a plurality of input terminals, wherein
said semiconductor circuit comprises an input circuit portion connected to said plurality of input terminals,
said inspection circuit comprising a logic circuit, supplied with a plurality of input signals from said input circuit portion, for performing a predetermined logic operation to said plurality of input signals to produce a logic operation result, whereby enabling to decide the presence or absence of said terminal open on the basis of the logic operation result.

2. The semiconductor circuit as claimed in claim 1, wherein said logic circuit comprises at least two different logic circuit portions.

3. The semiconductor circuit as claimed in claim 2, wherein said logic circuit comprises an OR circuit portion and an AND circuit portion as the at least two different logic circuit portions,
said OR circuit portion being configured to produce a signal of a logic “L” level if there is nothing wrong with said plurality of input terminals when all of said plurality of input terminals are supplied with the logic “L” level,
said AND circuit portion being configured to produce a signal of a logic “H” level if there is nothing wrong with said plurality of input terminals when all of said plurality of input terminals are supplied with the logic “H” level.

4. The semiconductor circuit as claimed in claim 3, wherein said OR circuit portion comprises a plurality of 2-input OR circuits which are cascade connected to said plurality of input terminals through said input circuit portion,
said AND circuit portion comprising a plurality of 2-input AND circuits which are cascade connected to said plurality of input terminals through said input circuit portion.

5. A semiconductor circuit as claimed in claim 3, wherein said semiconductor circuit has first and second output terminals, said semiconductor circuit comprising an output circuit portion connected to said first and said second output terminals,
wherein said inspection circuit further comprises an inverter for inverting an output signal of said OR circuit portion to supply an inverted signal to said first output terminal through said output circuit portion,
wherein an output signal of said AND circuit is supplied to said second output terminal through said output circuit portion.

6. A method of inspecting a terminal open of the semiconductor circuit as claimed in claim 3, said method comprising:
supplying all of said plurality of input terminals with one of the logic “H” level and the logic “L” level; and
supplying all of said plurality of input terminals with another of the logic “H” level and the logic “L” level,
whereby enabling to decide the presence or absence of the terminal open of said semiconductor circuit in accordance with a level of an output signal of said logic circuit.

7. A method of inspecting terminal opens of a semiconductor device comprising a plurality of semiconductor circuits each as claimed in claim 3 that are arranged in parallel, said method comprising:
connecting said plurality of input terminals of all of said semiconductor circuits in common, respectively;
supplying all of said plurality of input terminals with one of the logic “H” level and the logic “L” level; and
supplying all of said plurality of input terminals with another of the logic “H” level and the logic “L” level,
whereby enabling to decide the presence or absence of the terminal opens of said semiconductor device for said semiconductor circuits individually in accordance with a level of an output signal of said logic circuit.

8. The semiconductor circuit as claimed in claim 3, wherein said inspection circuit further comprises a plurality of inverters for alternately inverting input signals supplied from said plurality of input terminals through said input circuit portion.

9. A method of inspecting a terminal open of the semiconductor circuit as claimed in claim 8, wherein said method comprising:
supplying said plurality of input terminals with a bit parallel first input signal where logic levels are in turn inverted; and
supplying said plurality of input terminals with a bit parallel second input signal obtained by inverting the bit parallel first input signal,
whereby enabling to decide the presence or absence of the terminal open of said semiconductor circuit in accordance with a level of an output signal of said logic circuit.

10. A method of inspecting terminal opens of a semiconductor device comprising a plurality of semiconductor circuits each as claimed in claim 8 that are arranged in parallel, said method comprising:
connecting said plurality of input terminals of all of said semiconductor circuits in common, respectively;
supplying said plurality of input terminals with a bit parallel first input signal where logic levels are in turn inverted; and
supplying said plurality of input terminals with a bit parallel second input signal obtained by inverting the bit parallel first input signal,
whereby enabling to decide the presence or absence of the terminal opens of said semiconductor device for said semiconductor circuits individually in accordance with a level of an output signal of said logic circuit.
